(19) United States
(12) Patent Application Publication
(10) Pub. No.: US 2026/0212863 A1
(43) Pub. Date: Jul. 23, 2026

(54) NATURAL LANGUAGE TOOLS FOR PRECISE CONTROL AND NAVIGATION

(71) Applicant: AUTODESK, INC., San Francisco, CA (US)

(72) Inventors: George William FITZMAURICE, Toronto (CA); Justin Frank MATEJKA, Newmarket (CA); Jo Karel VERMEULEN, East York (CA)

(21) Appl. No.: 19/398,689

(22) Filed: Nov. 24, 2025

Related U.S. Application Data
(60) Provisional application No. 63/747,829, filed on Jan. 21, 2025.

(51) Int. Cl. G10L 15/22; G06F 30/12; G10L 15/02

(52) U.S. Cl. CPC G10L 15/22; G06F 30/12; G10L 15/02; G10L 2015/027; G10L 2015/223

(57) ABSTRACT

In various embodiments, a computer-implemented method for navigating design workspaces comprises acquiring, via an audio sensor, a speech input signal of a user, detecting, in the speech input signal, an initial lengthened command portion for a lengthened command to move at least a portion of a design object within a design workspace, detecting a lengthened command portion in a subsequent input signal of the user, in response to detecting the lengthened command portion, executing the lengthened command, where executing the lengthened command continues as the user continues to provide the subsequent input signal, and terminating execution of the lengthened command upon detecting an end of the lengthened command portion.

### CROSS-REFERENCE TO RELATED APPLICATIONS

This application claims priority benefit of the United States Provisional Patent Application titled “TECHNIQUES FOR NAVIGATING SOFTWARE APPLICATIONS USING NATURAL LANGUAGE,” filed on Jan. 21, 2025, and having Ser. No. 63/747,829. The subject matter of these related applications is hereby incorporated herein by reference.

### BACKGROUND

### Field of the Various Embodiments

The various embodiments relate generally to computer-aided design and, more specifically, to natural language tools for precise control and navigation.

### Description of the Related Art

Designers use computer-aided design (CAD) systems to generate complex designs using a suite of design and navigation tools. Among other things, CAD systems provide complex functions that precisely scale and move design objects and adjust characteristics of design objects, such as by changing mesh representations of design objects or materials used for design objects. Due to the complexity of creating designs, many designers require precise controls to add multiple design objects, size and align design objects in relation to existing design objects in a design workspace, and generate larger design workpieces using a plurality of subcomponent design objects. Conventional CAD systems include various types of manual input devices, such as a keyboard, mouse, digital pen, and a controller pad. One such input device receives input from a designer and responds to inputs by manipulating one or more design objects or changing the view of the design workspace. For instance, responding to the inputs can involve moving the camera within the design workspace by zooming in to a specific area or moving to a different area.

One drawback of conventional CAD systems is that such systems rely upon manual input devices to control the design objects within the workspace and navigate within the design workspace. As is well-understood, manually generating and modifying even a relatively simple design workpiece that includes multiple design objects is typically very labor-intensive and time-consuming. Because the time allocated for generating a design workpiece is usually limited, a designer normally can experiment with only a limited number of design objects when creating or modifying a design workpiece. Consequently, the designer inevitably uses a sub-optimized combination of design objects within the final design workpiece and/or fails to use certain design objects altogether within the final design workpiece, thereby reducing the overall quality of the final design workpiece.

Some conventional CAD systems use other types of input devices or sensors to control the manipulation of design objects or navigate through the design space. Other types of sensor-based input devices include gesture control and simple voice commands to perform functions similar to functions performed via manual input devices. These types of input devices can allow for more fluidity by the designer and are capable of responding to more natural instructions by the designer. However, sensor-based input devices are not as precise as manual input devices, resulting in the designer controlling design objects within the design workspace with limited precision. Due to the complexity of design workpieces that require precise sizing, spacing, and alignment of design objects, many designers refrain from using sensor-based input devices due to imprecision in control. As a result, many conventional CAD systems are inaccessible to designers that have limited abilities to manually control input devices. Further, many conventional CAD systems are unusable in some operating environments where manual input devices are not allowed or are overly cumbersome.

As the foregoing illustrates, there is a need in the art for more effective techniques for navigating within a design workspace when using CAD applications.

### SUMMARY

In various embodiments, a computer-implemented method for navigating design workspaces comprises acquiring, via an audio sensor, a speech input signal of a user, detecting, in the speech input signal, an initial lengthened command portion for a lengthened command to move at least a portion of a design object within a design workspace, detecting a lengthened command portion in a subsequent input signal of the user, in response to detecting the lengthened command portion, executing the lengthened command, where executing the lengthened command continues as the user continues to provide the subsequent input signal, and terminating execution of the lengthened command upon detecting an end of the lengthened command portion.

In various embodiments a computer-implemented method for navigating design workspaces comprises acquiring, via an audio sensor, a speech input signal of a user, detecting, in the speech input signal, a navigation command portion to move at least a portion of a design object within a design workspace, in response to detecting the navigation command portion, automatically generating a graphical overlay over at least a portion of the design workspace, where the graphical overlay includes a plurality of identifiers, detecting a subsequent navigation command identifying a selection of a first identifier included in the plurality of identifiers, and moving the portion of the design object to a location associated with the first identifier.

At least one technical advantage of the disclosed techniques relative to the prior art is that with the disclosed techniques, a computing device can respond to speech inputs with precise navigation and manipulation within a design workspace. In particular, a computing device implementing the disclosed design application can recognize and respond to specific types of voice commands and execute precise navigational controls in response to the voice command. In this manner, the disclosed design application can respond to a wider range of user inputs with precision when compared to conventional design applications that did not respond to such types of voice commands. A user interacting with the computing device implementing the disclosed design application can utilize voice commands to precisely manipulate objects or navigate within a design workspace without the need for manual input devices, such as a digital pen or mouse, which enhances the accessibility of the design application to a wider range of users and in a wider range of environments.

These technical advantages provide one or more technological advancements over prior art approaches.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 is a conceptual illustration of a system configured to implement one or more aspects of the various embodiments;

FIG. 2 is an illustration of the design application of FIG. 1 generating a lengthened command, according to various embodiments;

FIG. 3 is an illustration of the design application of FIG. 1 executing an example lengthened command within a design workspace, according to various embodiments;

FIG. 4 is an illustration of the design application of FIG. 1 executing another example lengthened command within a design workspace, according to various embodiments;

FIG. 5 sets forth a flow diagram for executing a lengthened command within a design workspace, according to various embodiments;

FIG. 6 is an illustration of the design application of FIG. 1 responding to an example navigation command using a series of landmark markers, according to various embodiments;

FIG. 7 is an illustration of the design application of FIG. 1 responding to another example navigation command using a labeled grid, according to various embodiments;

FIG. 8 is an illustration of the design application of successively responding to the example navigation command of FIG. 8 using a subsequent labeled grid, according to various embodiments;

FIG. 9 is an illustration of multiple labeled grid types generated by the design application of FIG. 1 in response to a navigation command, according to various embodiments;

FIG. 10 sets forth a flow diagram for executing a navigation command within a design workspace, according to various embodiments; and

FIG. 11 depicts one architecture of a system within which the various embodiments may be implemented.

### DETAILED DESCRIPTION

In the following description, numerous specific details are set forth to provide a more thorough understanding of the various embodiments. However, it will be apparent to one skilled in the art that the inventive concepts may be practiced without one or more of these specific details.

### System Overview

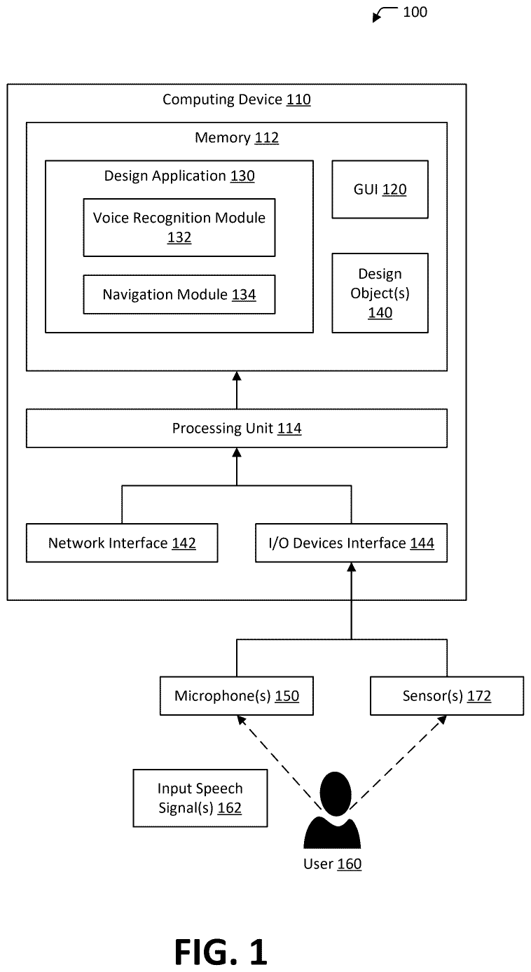

FIG. 1 is a conceptual illustration of a system 100 configured to implement one or more aspects of the various embodiments. As shown, the system 100 includes, without limitation, a computing device 110, one or more microphones 150, and one or more sensors 172. The computing device 110 includes, without limitation, memory 112, a processing unit 114, a network interface 142, and an input/output (I/O) interface 144. The memory 112 includes, without limitation, a design application 130, a graphical user interface (GUI) 120, and one or more design objects 140. The design application 130 includes, without limitation, a voice recognition module 132 and a navigation module 134.

In operation, a user 160 speaks one or more voice commands. The one or more microphones 150 acquire the speech of the user as the speech input signal 162. The processing unit 114 executes the design application 130, where the voice recognition module 132 included in the design application 130 processes the speech input signal 162 and generates the voice command. The navigation module 134 included in the design application 130 executes the voice command within a design workspace displayed in the GUI 120.

Any number of the components of the system 100 can be distributed across multiple geographic locations or implemented in one or more cloud computing environments (e.g., encapsulated shared resources, software, data) in any combination. In some embodiments, the computing device 110 and/or zero or more other client devices (not shown) can be implemented as one or more compute instances in a cloud computing environment, implemented as part of any other distributed computing environment, or implemented in a stand-alone fashion. In various embodiments, the computing device 110 can be integrated with any number and/or types of other devices (e.g., one or more other compute instances and/or a display device) into a user device. Some examples of user devices include, without limitation, desktop computers, laptops, smartphones, and tablets.

The computing device 110 includes the processing unit 114 and the memory 112. In various embodiments, the computing device 110 can be a device that includes one or more processing units 114, such as a system-on-a-chip (SoC). In some embodiments, the computing device 110 can include a wearable device, such as hearing aids, headphones, portable speakers, and/or other devices that include the processing unit 114. In other embodiments, the computing device 110 can be a tablet computer, desktop computer, mobile phone, media player, and so forth. Generally, the computing device 110 can be configured to coordinate the overall operation of the system 100. The embodiments disclosed herein contemplate any technically feasible system 100 configured to implement the functionality of the design application 130 via the computing device 110.

In various embodiments, one or more of computing device 110, sensor(s) 172, input device(s) 174, and/or output device(s) 176 may be included in one or more devices, such as mobile devices (e.g., cellphones, tablets, laptops, etc.), wearable devices (e.g., watches, rings, bracelets, headphones, etc.), consumer products (e.g., portable speakers, gaming, gambling, etc. products), smart home devices (e.g., smart lighting systems, security systems, digital assistants, etc.), communications systems (e.g., conference call systems, video conferencing systems, speaker amplification systems, etc.), and so forth. Computing device 110 may be located in various environments, including, without limitation, building environments (e.g., living room, conference room, conference hall, home office, etc.), road vehicle environments (e.g., consumer car, commercial truck, etc.), aerospace and/or aeronautical environments (e.g., airplanes, helicopters, spaceships, etc.), nautical and submarine environments, outdoor environments, and so forth.

The processing unit 114 can include a central processing unit (CPU), a digital signal processing unit (DSP), a microprocessor, an application-specific integrated circuit (ASIC), a neural processing unit (NPU), a graphics processing unit (GPU), a field-programmable gate array (FPGA), and so forth. The processing unit 114 generally comprises a programmable processor that executes program instructions to manipulate input data. In some embodiments, the processing unit 114 can include any number of processing cores, memories, and other modules for facilitating program execution. For example, the processing unit 114 could receive an input (e.g., the input speech signal 162 from the user 160) via the one or more microphones 150 and/or sensor data via the one or more sensors 172 and drive the design application 130 to execute commands corresponding to the inputs.

The memory 112 includes a memory module, or collection of memory modules. The memory 112 can include a variety of computer-readable media selected for their size, relative performance, or other capabilities: volatile and/or non-volatile media, removable and/or non-removable media, etc. The memory 112 can include cache, random access memory (RAM), storage, etc. The memory 112 can include one or more discrete memory modules, such as dynamic RAM (DRAM) dual inline memory modules (DIMMs). Of course, various memory chips, bandwidths, and form factors may alternately be selected.

Non-volatile memory included in the memory 112 generally stores application programs including the design application 130 and data (e.g., the design objects 140) associated with the design application 130. In various embodiments, the memory 112 can include non-volatile memory, such as optical drives, magnetic drives, flash drives, or other storage. In some embodiments, separate data stores, such as an external data store (not shown) can supplement the memory 112. The design application 130 within the memory 112 can be executed by the processing unit 114 to implement the overall functionality of the computing device 110 and, thus, to coordinate the operation of the system 100 as a whole.

In various embodiments, the memory 112 may include one or more modules for performing various functions or techniques described herein. In some embodiments, one or more of the modules and/or applications included in the memory 120 can be implemented locally on the computing device 110, and/or can be implemented via a cloud-based architecture. For example, any of the modules and/or applications included in the memory 120 could be executed on a remote device (e.g., smartphone, a server system, a cloud computing platform, etc.) that communicates with the computing device 110 via the network interface 142 or the I/O devices interface 144.

The design application 130 resides in the memory 112 and executes on the processing unit 114 of the computing device 110. The design application 130 may comprise a digital content creation (DCC) application, such as a computer-aided design (CAD) application, computer-aided engineering (CAE) application, simulator application, modeler application, geometry generator application, or the like. The design application 130 interacts with the user 160 via the GUI 120. In some embodiments, the design application 130 and one or more separate applications (not shown) interact with the same user via the GUI 120. In various embodiments, the design application 130 operates to generate and modify a design workpiece that includes one or more design objects 140. The design application 130 interacts with a user to generate the one or more design objects 140 via direct user input (e.g., one or more tools to generate 2D objects, 3D objects, wireframe geometries, meshes, etc.). For example, the design exploration application 130 can operate as an image editor to generate and modify 2D or 3D images. In another example, the design exploration application 130 can operate as a video editor application that generates and modifies audiovisual content.

The voice recognition module 132 performs various natural language processing (NLP) techniques, sentiment analysis, and/or speech analysis in order to parse the input speech signal 162 and identify any commands spoken by the user 160. In various embodiments, the voice recognition module 132 can determine a semantic meaning of speech made by the user 160 in order to detect a command in the input speech signal 162. In some embodiments, the voice recognition module 132 can perform sentiment analysis to determine the intended meaning of a phrase included in a command (e.g., identify a target design object 140, determine a target location, etc.). In some embodiments, the voice recognition module 132 can employ various statistical methods, machine-learning (ML) methods, state machines, and/or various other data structures in order to detect commands and/or the semantic meaning of phrases spoken by the user 160. Additionally or alternatively, the user 160 can train the ML models by providing feedback to certain identified words or speech portions. In some embodiments, a combination of training data (e.g., previous phrases, physiological metrics, etc.) can train the ML models. In various embodiments, the voice recognition module 132 determines whether a triggering event occurred that indicates that the navigation module 134 is to generate and/or execute a command. For example, the user 160 can speak a command that includes a specific trigger word or trigger phrase. In such instances, the voice recognition module 132 can generate one or more command portions that the navigation module 134 generates and/or executes.

The navigation module 134 performs various techniques to process commands and/or command portions generated by the voice recognition module 132. In various embodiments, the navigation module 134 can manipulate one or more design objects 140 within the design workspace based on the contents of the command included in the input speech signal 162. Additionally, or alternatively, the navigation module 134 can execute the command to navigate within the design workspace included in the GUI 120. For example, the navigation module 130 can receive a navigation command to move a design object 140. The navigation module 130 can then respond by executing the navigation command to move the design object 140 to a new location within the design workspace.

The GUI 120 can be any type of user interface that allows users to interact with one or more software applications via any number and/or types of GUI elements. The GUI 120 can be displayed in any technically feasible fashion on any number and/or types of stand-alone display devices, any number and/or types of display screens that are integrated into any number and/or types of user devices, or any combination thereof. The design application 130 can perform any number and/or types of operations to directly and/or indirectly display and monitor any number and/or types of interactive GUI elements and/or any number and/or types of non-interactive GUI elements within the GUI 120. In some embodiments, each interactive GUI element enables one or more types of user interactions that automatically trigger corresponding user events. Some examples of the types of interactive GUI elements include, without limitation, scroll bars, buttons, text entry boxes, drop-down lists, and sliders. In some embodiments, the application 130 organizes GUI elements into one or more container GUI elements (e.g., panels and/or panes). For example, the design application 130 can display the design workspace and one or more GUI elements as windows proximate to the design workspace.

In various embodiments, the GUI 120 includes the design workspace (not shown). In various embodiments, the design workspace is a volumetric space that displays one or more geometries of design objects 140 that are part of a design workpiece. The design workspace can include two-dimensional (e.g., panels, textures, overlays, etc.) and/or three-dimensional content. In various embodiments, the design application 130 enables the user 160 to manipulate a camera within the design workspace using one or more tools (not shown), such as the navigation module 134 to control the roll, pitch, yaw, zoom level, etc., of the camera. Additionally or alternatively, the design application 130 includes controls and/or tools (e.g., voice commands via the voice recognition module and/or the navigation module 134) to sketch images, create new geometries and textures, and/or edit existing geometries of one or more design objects 140. In various embodiments, the design workspace can include multiple design objects 140 that combine to form a design workpiece. For example, the design workspace can include a plurality of subcomponents corresponding to separate design objects 140 that combine to form a design workpiece for a gearbox. The one or more design objects 140 include geometries, textures, images, and/or other components that the design application 130 uses to generate a design workpiece. In various embodiments, the geometry of a given design object 140 refers to any multi-dimensional model of a physical structure, including CAD models, meshes, and point clouds, as well as circuit layouts, piping diagrams, free-body diagrams, and so forth. In some embodiments, the design application 130 stores multiple design objects 140 for a given design workpiece.

In some embodiments, computing device 110 may communicate with other devices, such as one or more microphones 150, one or more sensors 172, one or more input devices, and/or output devices (not shown), using the input/output (I/O) devices interface 144. In such instances, the I/O devices interface 144 can include a number of different I/O adapters or interfaces used to provide the functions described herein. For example, the I/O devices interface 144 can include wired and/or wireless connections, and can use various formats or protocols. In another example, the computing device 110, through the I/O devices interface 144, can receive one or more input speech signals 162, and/or can detect physiological data, visual data, and so forth using the one or more sensors 172. In various embodiments, the I/O devices interface 144 connects to one or more input devices capable of receiving input, such as a keyboard, a mouse, a touch-sensitive screen, a digital pen, and/or other input devices for the user 160 to manually provide input data to the computing device 110. For example, input from the user 160 can include gestures, such as various movements or orientations (e.g., body pose) of the hands, arms, eyes, or other parts of the body that are received via a camera. In various embodiments, the user 160 can trigger the design application 130 to initiate or complete the execution of a command by providing a manual input via an input device.

In some embodiments, the computing device 110 may communicate with other devices, such as an external data store, using the network interface 142 and via a network (not shown). In some embodiments, other types of networked computing devices (not shown) can connect to the computing device 110 via the network interface 142. Examples of networked computing devices include a server, a desktop computer, a mobile computing device, such as a smartphone or tablet computer, and/or a worn device, such as a wristwatch, headphones, or a head-mounted display device. In some embodiments, the networked computing devices can be used as sensors 172, input devices 174, and/or output devices 176.

In various embodiments, the one or more microphones 150 include a single microphone and/or a microphone array that acquires sound data, such as the input speech signal 162. In various embodiments, the microphone 150 can be directional (e.g., user-facing microphone, beamforming microphone array, etc.) and acquire auditory data from a specific person, such as the user 160. Such sound data can be processed by voice recognition application 132 using various audio processing techniques. The one or more microphones 150 can be a plurality of audio sensors or other transducers or sensors capable of converting sound waves into an electrical signal. The one or more microphones 150 may include an array of sensors that includes sensors of a single type, or a variety of different sensors.

The one or more sensors 172 include one or more devices that collect data associated with objects in an environment. In various embodiments, the sensor(s) 172 can include groups of sensors that acquire different sensor data. For example, the sensor(s) 172 can include a reference sensor, such as a microphone 150 and/or a visual sensor (e.g., camera, thermal imager, linear position sensor, etc.), which could acquire auditory data, visual data, physiological data, and so forth. The one or more sensors 172 include one or more devices that perform measurements and/or acquire data related to certain subjects in an environment. In various embodiments, the one or more sensors 172 can generate sensor data that is related to the user 160. For example, the one or more sensors 172 can collect biometric data related to the user 160 (e.g., visible perspiration, muscle movement, breathing rate, pupil size, eye saccades, temporary change in skin color, etc.). and/or the user 160 when speaking (e.g., heart rate, brain activity, skin conductance, blood oxygenation, galvanic skin response, blood-pressure level, average blood glucose concentration, etc.). Further, the sensor(s) 172 can include a user-facing camera that records the face of the user 160 as image data. Similarly, the one or more sensors 172 can include a facial electromyography (fEMG) sensor that measures specific muscle contractions and associated activities (e.g., a raised eyebrow, clenched jaw, etc.), of the user 160. The design application 130 can then analyze the image data in order to determine the facial expression of the user 160 to detect a trigger condition. In another example, one or more sensors 172 can include sensors that acquire biological and/or physiological signals of the user 160 when speaking (e.g., perspiration, heart rate, heart-rate variability (HRV), blood flow, blood-oxygen levels, breathing rate, galvanic skin response (GSR), sounds created by a user, behaviors of a user, etc.). Additionally, the one or more sensors 172 can include a pupil sensor (e.g., a camera focused on the eyes of the user 160) that acquires image data about at least one pupil of the user 160. The design application 130 can then perform various pupillometry techniques to detect eye parameters (e.g., fluctuations in the pupil diameter, eye gaze direction, eyelid position, eye saccades, etc.) as physiological data.

### Natural Language Tools for Precise Control via Expressive Lengthening

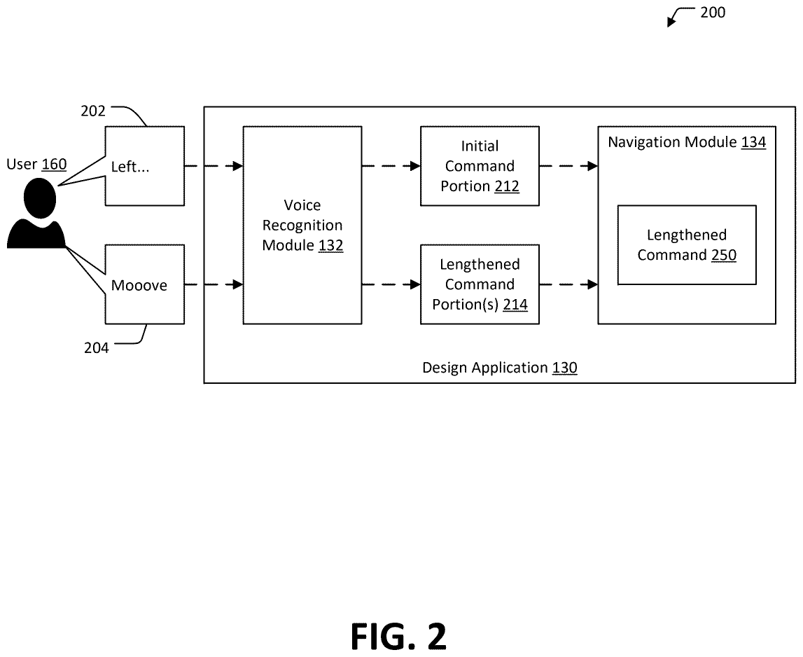

FIG. 2 is an illustration of the design application 130 of FIG. 1 generating a lengthened command 250, according to various embodiments. As shown, a visualization 200 of the interaction includes, without limitation, the user 160, an initial input speech signal 202, a subsequent input speech signal 204, and the design application 130. The design application 130 includes, without limitation, the voice recognition module 132, the navigation module 134, an initial command portion 212, and a lengthened command portion 214. The navigation module 134 includes, without limitation, the lengthened command 250.

In operation, the voice recognition module 132 included in the design application 130 receives multiple speech input signals that are associated with a lengthened command to control the manipulation of a design object 140 within the design workspace. In various embodiments, the lengthened command 250 includes a trigger word or phrase that causes the design application 130 to detect a command associated with the design application 130. The lengthened command also includes one or more lengthened command portions 214 that control the execution of the lengthened command 250 in real time. In various embodiments, the user 160 speaks an initial phrase to trigger the beginning of a lengthened command. The user 160 then controls the execution of a command through expressive lengthening (“affective lengthening”) to continue pronunciation of a syllable to control the extent that the design application 130 executes the lengthened command. For example, the user 160 can trigger the navigation module 134 to move a selected design object 140 within the design space by initially speaking “left” as a trigger. The user 160 can then control the amount of the navigation module 134 by lengthening the pronunciation of the word “move,” continuing with the pronunciation of the “/u/” syllable in “move” until the design object 140 is at the target location. In this manner, the design application 130 can respond to the voice input of the user in real time as the user 160 pronounces lengthened words, enabling the design application 130 to precisely respond to the beginning and ending of the pronunciation of the lengthened syllable.

In various embodiments, the voice recognition module 132 processes the initial speech input signal 202 to detect whether the user 160 is providing a command. In some embodiments, the command is the lengthened command 250, where the voice recognition module 132 detects and transmits an initial command portion 212 to the navigation module 134. In such instances, the navigation module 134 executing the lengthened command 250 is initiated by the voice recognition module 132 receiving the one or more subsequent speech input signals 204 and transmitting the lengthened command portions 214 to the navigation module 134. The navigation module 134 can generate and/or execute the lengthened command 250 based on the initial command portion 212 and the one or more lengthened command portions 214. For example, the user can generate the one or more subsequent speech input signals 204 by lengthening the pronunciation of one or more syllables of a control phrase (e.g., “moooove,” “rooootate,” “stretch over therrrre,” etc.) and/or a lengthening sound (e.g., “ehhhh... stop.”). In such instances, the navigation module 134 executes the command until the design application 130 detects the end of the lengthened syllable and/or detects another trigger event via a non-auditory input (e.g., snapping fingers, tilting a head, pressing a controller input, etc.).

In various embodiments, the initial command portion 212 can include identifying information (e.g., the portion of the design object 140 that is to be selected). In some embodiments, the initial command portion 212 can include a manipulation action. The manipulation action can indicate characteristics of the manipulation that the navigation module 134 is to perform. For example, when the lengthened command 250 is a movement of a design object 140, the initial command portion 212 can include information that specifies the movement direction. In such instances, the navigation module 134 can determine which design object 140 to manipulate and how to execute the manipulation action before the voice recognition module 132 detects the lengthened command portions 214.

Additionally, or alternatively, the command is a set of navigation commands (not shown), where the voice recognition module 132 detects an initial navigation command in the initial speech input signal 202 and detects a subsequent navigation command in the subsequent speech input signal 204. In such instances, the voice recognition module 132 can detect the initial navigation command, whereupon the navigation module 134 automatically responds by displaying a graphical overlay. The voice recognition module 132 can then detect the subsequent navigation command that includes a selection of an identifier in the graphical overlay. In such instances, the navigation module 134 can manipulate a design object 140 by moving the design object 140 to a location corresponding to the selected identifier.

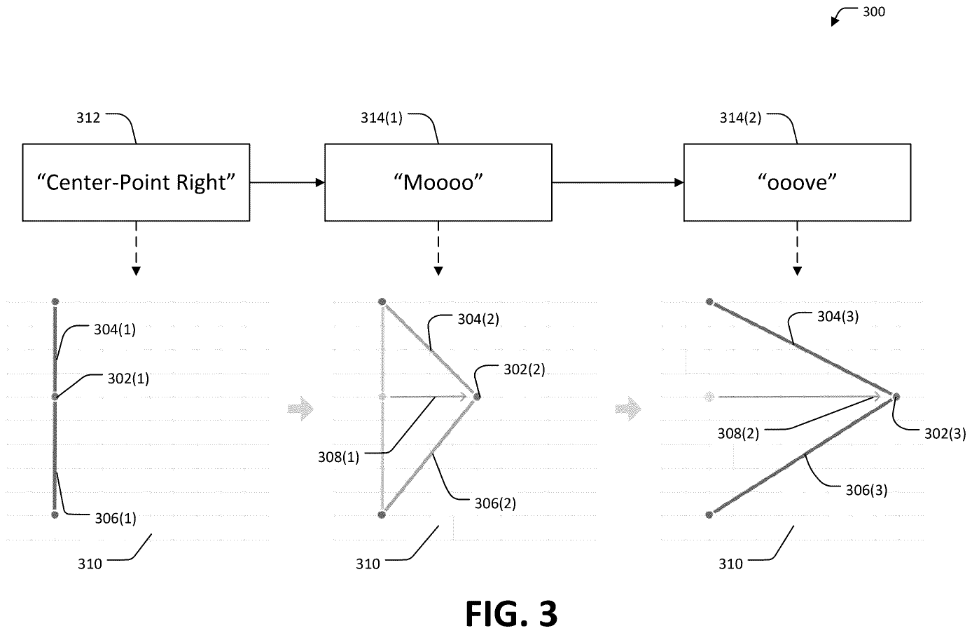

FIG. 3 is an illustration of the design application 130 of FIG. 1 executing an example lengthened command 250 within a design workspace, according to various embodiments. As shown, the visualization 300 includes, without limitation, a design workspace 310, a selected object point 302, line segments 304 and 306, a movement path 308, an initial command portion 312, and a plurality of lengthened command portions 314.

When the user 160 speaks the lengthened command 250, the navigation module 134 executes the lengthened command by identifying the target portion of the design object 140 and executing the requested manipulation. As shown, the lengthened command 250 specifies that the center point of the line connecting the line segment 304 and the line segment 306 is to be moved to the right within the design workspace 310. The navigation module 134 initiates the manipulation of the design object 140 by identifying and selecting the center point (e.g., the selected object point 302(1)). When the user 160 speaks the lengthened syllable included in the first lengthened command portion 314(1), the navigation module 134 responds by moving the selected object point 302(2) in the specified direction along the movement path 308(2), thereby extending the line segments 304(2) and 306(2). Alternatively, when the user specifies movement of the entire line, the navigation module 134 can respond by moving the entire line without extending the line segments 304(1) and 306(1).

The navigation module 134 responds to the lengthened command portion 314(1) in real-time, continuing the execution of the lengthened command 250 by continuing to move the selected object point 302(2) along the movement path 308(1) as the user 160 continues to pronounce the lengthening syllable. In some embodiments, the lengthened syllable is included in a manipulation phrase that specifies how the portion of the design object 130 is to be manipulated (e.g., “moooove”). Alternatively, in some embodiments, the lengthened syllable is included in another word or sound (e.g., “move tiiiiiilllllll there,” or “start, ehhhhh, stop.”).

In some embodiments, the navigation module 134 can change how the navigation module 134 executes the lengthening command based on the characteristics of the voice. For example, the voice recognition module 132 and/or the navigation module 134 can detect tonal and/or other auditory qualities of the voice of the user 160 when pronouncing the lengthened syllable, such as pitch, inflection, loudness, change in speed, etc. In such instances, the navigation module 134 can modify the execution of the lengthened command 250 by changing the speed and/or direction (e.g., up and down) of the movement path based on changes in the tonal and/or auditory qualities of the lengthened syllable. In various embodiments. Additionally, or alternatively, the navigation module 134 can modify the execution of the lengthened command 250 based on other sensor data, such as body pose and head tilt, and/or body movements.

When the user 160 finishes pronunciation of the lengthened syllable 250, the voice recognition module 132 and/or the navigation module 134 detects the end of the lengthened syllable in the lengthened command portion 314(2) (e.g., the pronunciation of “/v/” in “move”). The navigation module 134 determines that the execution of the lengthened command 250 is complete and the selected object point 302(3) completes the movement along the movement path 308(2), further extending the line segments 304(3) and 306(3).

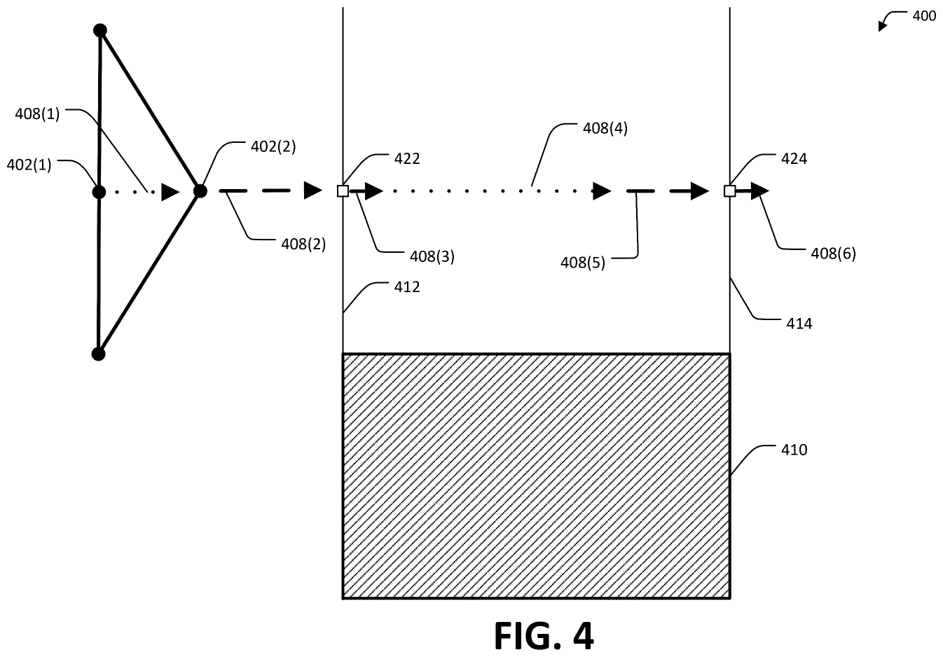

FIG. 4 is an illustration of the design application 130 of FIG. 1 executing another example lengthened command 250 within a design workspace 400, according to various embodiments. As shown, the design workspace 400 includes, without limitation, a selected object point 402, a movement path 108, an existing design object 410, alignment lines 414 and 414, and candidate alignment locations 422 and 424.

In various embodiments, the navigation module 134 can determine one or more landmark locations within the design space 200 as candidates for the target location to move the selected object point 402. In such instances, the navigation module 134 can perform techniques to snap the selected object point 402 to one or more of the candidate landmark locations to aid in the precise manipulation of the selected object point 402. For example, the navigation module 134 can analyze the design space and determine various landmark locations associated with vertices, edges, midpoints, and/or centers of existing design objects (e.g., the existing design object 410) included in the design workspace 400. In some embodiments, the design application 130 and/or the navigation module 134 can train a ML model to receive an input of the design workspace 400 (e.g., one or more 2D and/or 3D images) and output a set of candidate landmark locations within the design workspace 400 based on the locations of objects and/or other locations (e.g., a center or edge of the design workspace) within the design workspace 400. In such instances, the navigation module 134 can identify and/or display the set of candidate landmark locations.

For example, as shown, the navigation module 134 can identify the candidate alignment locations 422 and 424 based on the intersection of the movement path 408 with edges of the existing design object 410. In such instances, the navigation module 134 can display the alignment lines 412 and 414 to highlight potential locations where the selected object point aligns with the edge of the existing design object 410. When the navigation module 134 executes the lengthened command 250 by moving the selected object point 402 along the movement path 408(1), the navigation module 134 continues to refine the execution. The navigation module 134 can then modify the execution of the lengthened command 250 based on proximity to a candidate landmark location. For example, when the selected object point 402 is within a threshold distance to the candidate alignment location 422, the navigation module 134 can snap (e.g., the movement 408(2)) the selected object point 402 to the candidate alignment location 422 instead of moving the selected object point 402 at a constant speed (e.g., 408(1)). Additionally, or alternatively, the navigation module 134 can slow or stop movement (e.g., 408(3)) along the movement path 408 when the selected object point is at the candidate alignment location 422 (e.g., a “stay snapped” action) for a threshold period of time before continuing along the movement path at the constant speed (e.g., 408(4)). The navigation module can then repeat the snapping actions (e.g., 408(5), 408(6)) for the other locations.

In some embodiments, the navigation module 134 can calibrate for the termination of the lengthened command 250 to account for a time delay between the user 160 completing pronunciation of the syllable and the navigation module 134 terminating execution of the lengthened command 250. For example, the navigation module 134 can calibrate for a time delay between the user 160 speaking phrases and the navigation module 134 terminating execution. Additionally, or alternatively, the navigation module 134 can include a calibrated corrective action (e.g., a “step-back” option) to account for any delays. For example, the navigation module 134 can reverse and/or step forward for a specific distance within the design workspace 400 based on a determined calibration delay.

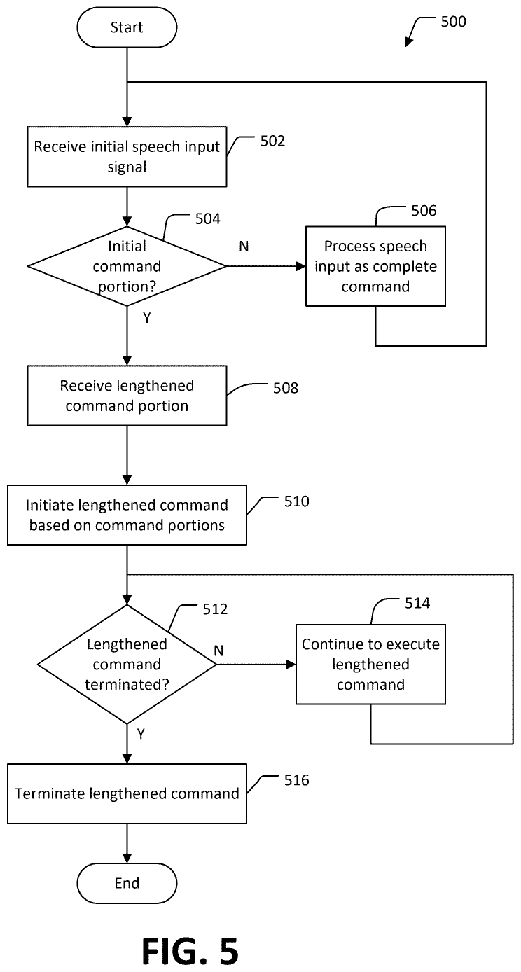

FIG. 5 sets forth a flow diagram for executing a lengthened command within a design workspace, according to various embodiments. Although the method steps are described with reference to the systems of FIGS. 1-4, 6-9, and 11, persons skilled in the art will understand that any system configured to implement the method steps, in any order, falls within the scope of the embodiments.

As shown, the method 500 begins at step 502, where the design application receives an initial speech signal 202. In various embodiments, the voice recognition application 132 included in the design application 130 receives the initial speech input signal 202 from the user via one or more microphones 150. In various embodiments, the initial speech input signal 202 includes a portion of the lengthened command 250 and/or other voice commands.

At step 504, the design application 130 determines whether the initial speech signal 202 includes an initial command portion 212. In various embodiments, the voice recognition module 132 processes the initial speech input signal 202 to detect whether the user 160 is providing a lengthened command 250. In such instances, the voice recognition module 132 detects and transmits an initial command portion 212 to the navigation module 134. When the design application 130 determines that the initial speech input signal 202 includes the initial command portion 212, the design application 130 proceeds to step 508. Otherwise, the design application 130 determines that the initial speech input signal 202 does not include the initial command portion 212 and proceeds to step 506, where the design application 130 processes the initial speech input signal 202 as a complete command.

At step 508, the design application 130 receives a lengthened command portion 214. In various embodiments, the user 160 continues speaking the lengthened command 250 by speaking one or more subsequent speech input signals 204 that include the pronunciation of one or more syllables of a control phrase (e.g., “moooove,” “rooootate,” “stretch over therrrre,” etc.) and/or a lengthening sound (e.g., “ehhhh . . . stop.”). In such instances, the voice recognition module 132 generates one or more lengthened command portions 214 and transmits the lengthened command portion 214 to the navigation module 134.

At step 510, the design application 130 initiates the lengthened command 250 based on the initial command portion 212 and the lengthened command portion 214. In various embodiments, the navigation module 134 generates and executes the lengthened command 250. In various embodiments, the initial command portion 212 can include identifying information (e.g., the portion of the design object 140 that is to be selected) and/or a manipulation action. The manipulation action can indicate characteristics of the manipulation that the navigation module 134 is to perform. For example, when the lengthened command 250 is a rotation of a design object 140, the initial command portion 212 can include information that specifies the rotation direction. In such instances, the navigation module 134 can determine which design object 140 to manipulate and how to execute the manipulation action (e.g., rotate around the center of the design object 140 or another location) before the voice recognition module detects the lengthened command portions 214. The navigation application 134 then executes the lengthened command 250 upon receiving the lengthened command portion 214 from the voice recognition module 132.

At step 512, the design application 130 determines whether the lengthened command 250 has terminated. In various embodiments, the navigation module 134 continues execution of the lengthened command 250 until the design application 130 detects the termination of the lengthened command 250. In some embodiments, the navigation module 134 detects the end of the lengthened syllable. Alternatively, in some embodiments, the navigation module 134 detects another trigger event via a non-auditory input (e.g., snapping fingers, tilting a head, pressing a controller input, etc.). When the design application 130 detects the termination of the lengthened command, the design application proceeds to step 516. Otherwise, the design application 130 does not detect the termination of the lengthened command 250 and proceeds to step 514.

At step 514, the design application 130 continues to execute the lengthened command 250. In various embodiments, the user 160 then controls the execution of the lengthened command 250 by using expressive lengthening continue pronunciation of a syllable to cause the navigation module 134 to continue execution of the lengthened command 250. For example, the user 160 can trigger the navigation module 134 to rotate a selected design object 140 within the design space by initially speaking “clockwise” as a trigger. The user 160 can then control the amount of the navigation module 134 by lengthening the pronunciation of the word “rotate,” continuing with the pronunciation of the “/ [symbol] /” or “/te/” syllables in “rotate” until the design object 140 is in the correct position within the design workspace 400. Upon continuing the execution of the lengthened command, the design application 130 returns to step 512.

At step 516, the design application 130 terminates the lengthened command 250. In various embodiments, the navigation module 134 terminates execution of the lengthened command in response to detecting the termination of the command by the user 160. In some embodiments, the navigation module 134 can calibrate for the termination of the lengthened command 250 to account for a time delay between the user 160 completing pronunciation of the syllable and the navigation module 134 terminating execution of the lengthened command 250. For example, the navigation module 134 can calibrate for a time delay between the user 160 speaking phrases and the navigation module 134 terminating execution. Additionally, or alternatively, the navigation module 134 can include a calibrated corrective action (e.g., a “step-back” option) to account for any delays. For example, the navigation module 134 can reverse and/or step forward for a specific distance within the design workspace 400 based on a determined calibration delay.

### Natural Language Navigation Controls

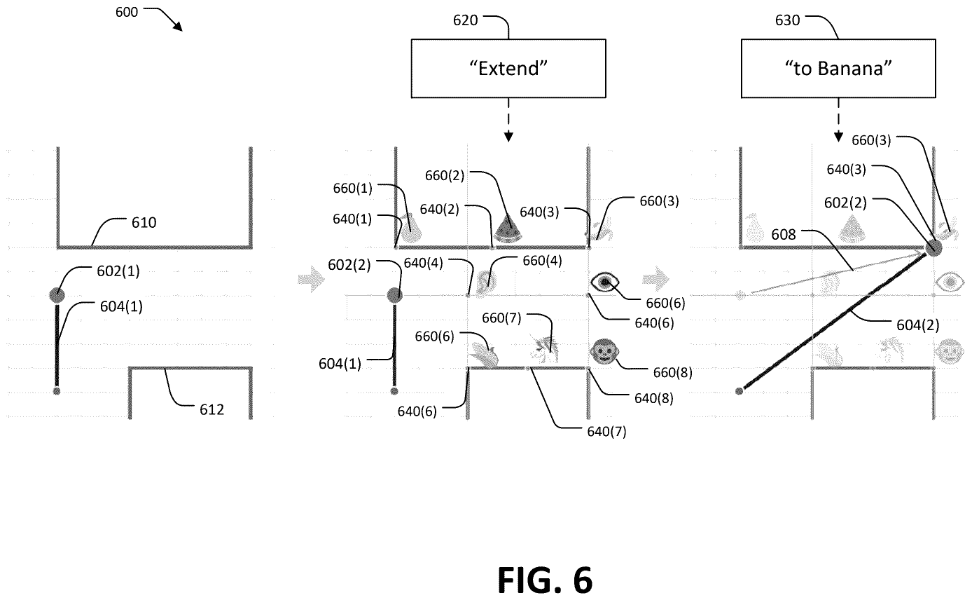

FIG. 6 is an illustration of the design application of FIG. 1 responding to an example navigation command 620 using a series of landmark markers 660, according to various embodiments. As shown, the visualization 600 includes a selected object point 602, a line segment 604, existing design objects 610 and 612, an initial navigation command 620, a subsequent navigation command 630, a plurality of candidate landmark locations 640, and a plurality of landmark markers 660.

In operation, the voice recognition module 132 detects the initial navigation command 620 in the initial speech input signal 202 and detects the subsequent navigation command 630 in the subsequent speech input signal. When the navigation module 134 receives the initial navigation command 240, the navigation module 134 automatically responds to the initial navigation command 240 by displaying a graphical overlay (e.g., the landmark markers 660). The voice recognition module 132 can then detect the subsequent navigation command 630 that includes a selection of an identifier in the graphical overlay. In such instances, the navigation module 134 can manipulate a design object 140 based on the selection of the identifier. For example, the navigation module 134 can execute the navigation command by moving the selected object point 602(1) to a location (e.g., the candidate landmark location 640(3)) corresponding to the selected identifier (e.g., the banana icon 660(3)).

In various embodiments, the navigation module 134 can determine one or more landmark locations within the design space as candidates for the target location to move the selected object point 602. For example, the navigation module 134 can analyze the design space and determine various landmark locations associated with vertices, edges, midpoints, and/or centers of existing design objects (e.g., the existing design objects 610 and 612) included in the design workspace. In some embodiments, the design application 130 and/or the navigation module 134 can train a ML model to receive an input of the design workspace (e.g., one or more 2D and/or 3D images) and output a set of candidate landmark locations 660 within the design workspace based on the locations of objects and/or other locations (e.g., a center or edge of the design workspace) within the design workspace. In such instances, the navigation module 134 can identify and/or display the set of candidate landmark locations 640. In some embodiments, the navigation module 134 determines the candidate landmark locations 640 prior to receiving the initial navigation command 620. For example, the navigation module 134 can periodically determine the candidate landmark locations 660 based on the edges and vertices of the existing design objects 610 and 612 and store the candidate landmark locations 640 as persistent locations.

Additionally, or alternatively, in some embodiments, the navigation module 134 can determine the candidate landmark locations 640 in response to receiving the initial navigation command 620. In such instances, the candidate landmark locations 640 can include locations associated with the selected object point 602. For example, the candidate landmark locations 640(4) and 640(6) correspond to intersections locations along the same horizontal line of the selected object point 602 that intersect alignment lines for the edges of the existing design object 612.

In various embodiments, the navigation module 134 can generate a graphical overlay comprising a plurality of landmark markers 660 (e.g., 660(1)-660(8)) to uniquely identify each of the candidate landmark locations 640 (e.g., 640(1)-640(8)) to aid in the precise manipulation of the selected object point 402. The landmark markers 660 can be a set of stored icons, letters, numbers, and/or symbols that can identify a specific candidate landmark location. In some embodiments, the plurality of landmark markers 660 can include multiple copies of the same icon. In such instances, the navigation module 134 can place copies of the landmark markers 660 at similar locations (e.g., a carrot icon at each center point of each circle in the design workspace) and the user can specify a specific copy of the icon and/or cycle through copies of the icon (e.g., “move to the next carrot; now extend to the third carrot.”). In various embodiments, the navigation module 134 stores phonetically distinct icons to increase the distinguishing features of the icon. For example, the plurality of icons can include a pear, a carrot, and corn, but can exclude a horn. In another example, the markers can be symbols representing code words in a phonetic alphabet (e.g., foxtrot, golf, hotel, India, etc.).

Upon the navigation module 134 displaying the graphical overlay of landmark markers 660, the user can speak the subsequent navigation command 630 selecting a specific landmark marker 660 and/or set of markers (e.g., “zoom to banana, monkey, corn,” to zoom to an area defined by locations proximate to the markers 660(3), 660(8), and 660(6)). The navigation module 134 can then execute the navigation command 250 based on the selection specified in the subsequent navigation command 630. For example, as shown, the navigation module 134 can move the selected object point 602(2) to the candidate landmark location 640(3) that corresponds to the selected landmark marker 660(3). In various embodiments, the navigation module 134 can animate the movement of the selected object point 602 along the movement path 608, thereby extending the length of the line segment 604 (e.g., 604(2)). Alternatively, the navigation module 134 can snap (e.g., the movement 608) the selected object point 602(2) to the candidate landmark location 604(3) without animating the movement.

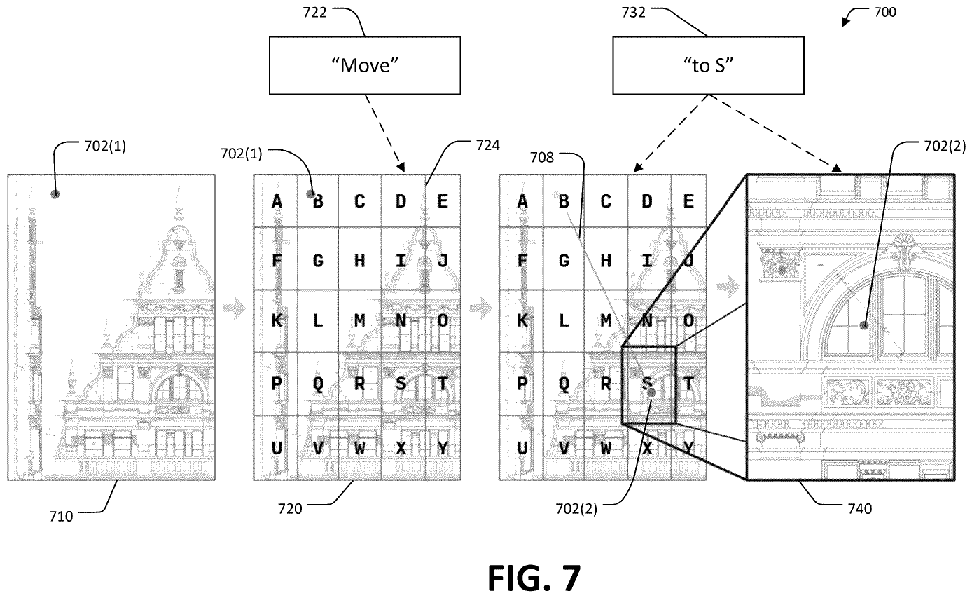

FIG. 7 is an illustration of the design application 130 of FIG. 1 responding to another example navigation command using a labeled grid 724, according to various embodiments. As shown, the visualization 700 includes, without limitation, a first design workspace view 710, a second design workspace view 720, a third design workspace view 740, an initial navigation command 722, a subsequent navigation command 732, a selected object point 702, the labeled grid 724, and the movement path 708.

In operation, the navigation module 134 can respond to an initial navigation command 722 by generating a graphical overlay that comprises a labeled grid 724 of the design workspace, producing the second design workspace view 720. Each grid area in the labeled grid 724 is labeled with a distinct identifier (e.g., the letter “B” identifying the grid area that contains the selected object point 702(1)). When the user speaks a distinct identifier, the navigation module 134 moves the selected object point 702(2) to the corresponding grid area. Additionally, or alternatively, the navigation module 132 can also change the view by zooming into an area that includes at least the selected grid area. For example, the navigation module 134 can zoom in from the second design workspace view 720 to display the third design workspace view 740 that includes the entirety of the “S” grid area and portions of neighboring grid areas (to aid in moving the selected object point 702 to an edge of the selected grid area). In some embodiments, the navigation module 134 animates the movement of the selected object point 702 along the movement path 708, then animates the zooming of the camera view. Alternatively, the navigation module 134 can update the design workspace to the third design workspace view 740 without animating the execution of the navigation command.

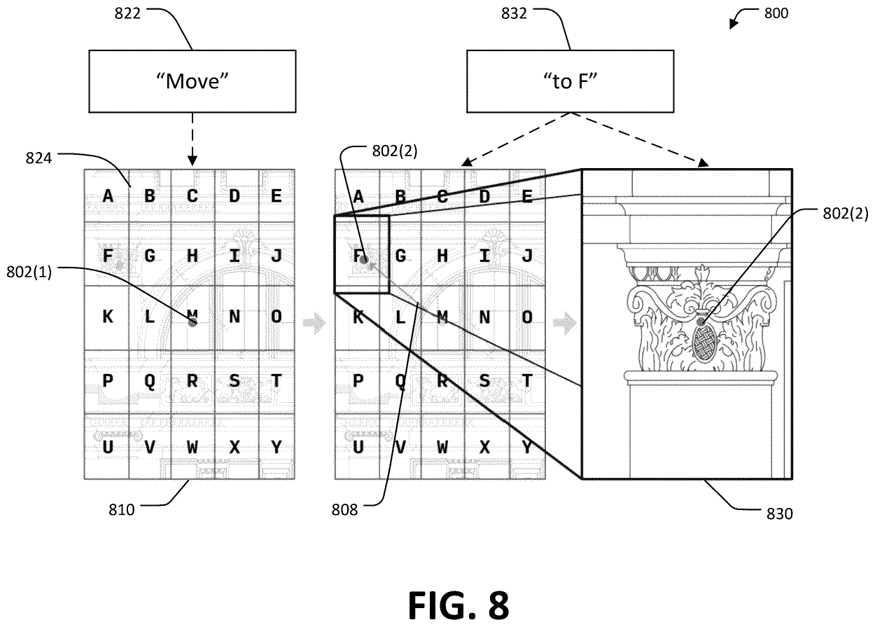

FIG. 8 is an illustration of the design application of successively responding to the example navigation command of FIG. 8 using a subsequent labeled grid, according to various embodiments. As shown, the visualization 800 includes, without limitation, a fourth design workspace view 810, a fifth design workspace view 830, a successive navigation command 822, a subsequent successive navigation command 832, a selected object point 802, the successive labeled grid 824, and a movement path 808.

In various embodiments, the navigation module 134 can perform multiple successive zooms of grid areas selected by the user 160 to zoom into a specific portion of the design workspace. For example, the navigation module 134 can respond to receiving the successive navigation command 822 by updating the third design workspace view 740, which corresponds to the selected grid, by generating the fourth design workspace view 810 that includes a successive labeled grid 824. The successive labeled grid 824 can be of similar form as the labeled grid 724 with a similar number of grid areas and grid shapes. Alternatively, the successive labeled grid 824 can include a different quantity of grid areas than the quantity of grid areas included in the labeled grid 724.

When the navigation module 134 receives the subsequent successive navigation command 832 that selects a specific grid area in the successive labeled grid 824, the navigation module 134 can respond by moving the selected object point 802 along the movement path 808 to the selected grid area. Additionally, in some embodiments, the navigation module 134 automatically updates to the fourth design workspace view 830 by zooming in to an area surrounding the selected grid area. In this manner, the navigation module 134 can generate successive labeled grids and move and zoom to successive grid areas within the successive labeled grids based on selections made by the user 160 to precisely move the selected object point 802 to a specific location within the design workspace via voice commands with high precision.

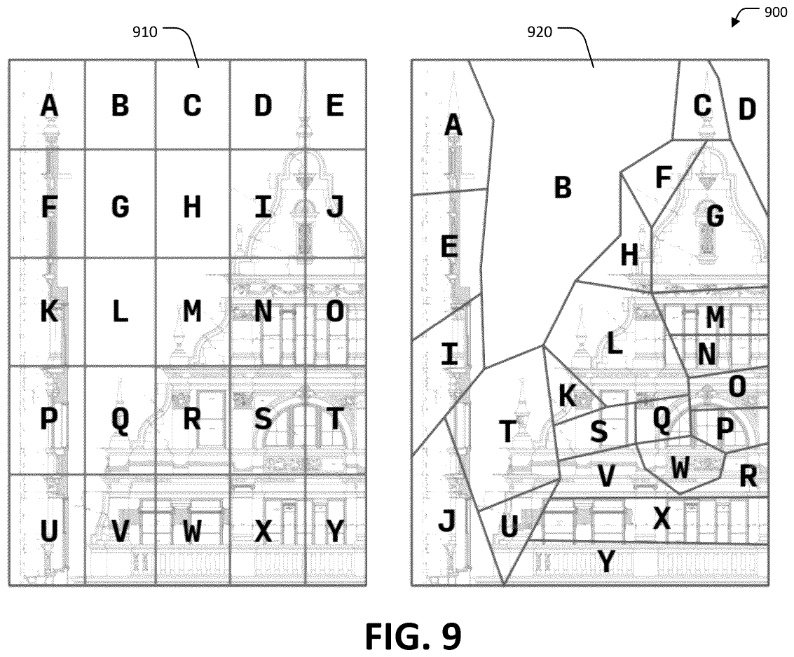

FIG. 9 is an illustration of multiple labeled grid types 910 and 920 generated by the design application 130 of FIG. 1 in response to a navigation command, according to various embodiments. As shown, the visualization 900 includes a uniform grid type 910 and a non-uniform grid type 920.

In various embodiments, the navigation module 134 can store configuration preferences that specify the grid type to display in response to a navigation command. For example, the navigation module 134 can automatically display the uniform grid type 910 as a default upon receiving a navigation command. In some embodiments, the configuration preferences can specify the grid area shape, number of grid areas, identifier type (e.g., alphabetical, numeric, symbols, icons, etc.), and so forth.

Additionally, or alternatively, in some embodiments, the navigation module 134 can generate a non-uniform grid type 920. In such instances, the navigation module 134 can determine the grid area sizes and shapes by analyzing the design workspace. For example, the navigation module 134 can determine grid size as inversely proportional to the number of design objects 140 and/or details within the design workspace. In such instances, areas that include more design objects 140 or details are included in smaller grid areas, while areas with large amounts of white space are included in fewer, larger grid areas.

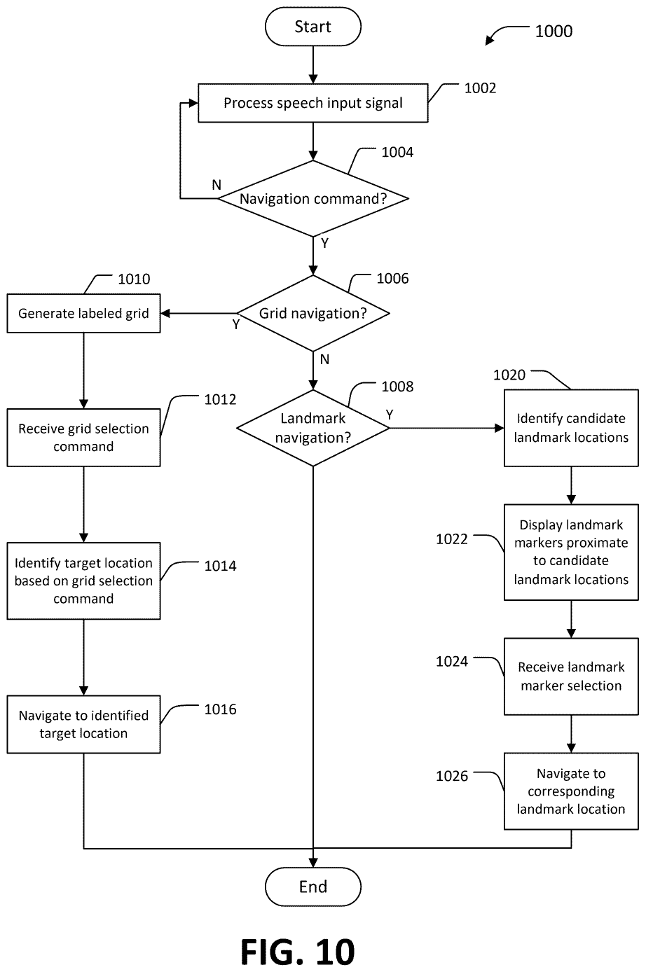

FIG. 10 sets forth a flow diagram for executing a navigation command within a design workspace, according to various embodiments. Although the method steps are described with reference to the systems of FIGS. 1-4, 6-9, and 11, persons skilled in the art will understand that any system configured to implement the method steps, in any order, falls within the scope of the embodiments.

As shown, the method 1000 begins at step 1002, where the design application 130 processes a speech input signal 202. In various embodiments, the voice recognition application 132 included in the design application 130 receives the initial speech input signal 202 from the user 160 via one or more microphones 150. In various embodiments, the initial speech input signal 202 includes a navigation command and/or other voice commands.

At step 1004, the design application 130 determines whether the speech input signal 202 includes a navigation command. In various embodiments, the voice recognition module 132 processes the initial speech input signal 202 to detect whether the user 160 is providing an initial navigation command 620. In such instances, the voice recognition module 132 detects and transmits the initial navigation command 620 to the navigation module 134. When the design application 130 determines that the initial speech input signal 202 includes the initial navigation command 620, the design application 130 proceeds to step 1006. Otherwise, the design application 130 determines that the initial speech input signal 202 does not include the initial navigation command 620 and returns to step 1002, where the design application 130 processes additional speech input signals 202.

At step 1006, the design application 130 determines whether to perform navigation using a labeled grid 724. In various embodiments, the navigation module 134 determines whether to respond to the initial navigation command 620 by generating a grid overlay, such as the labeled grid 724. In some embodiments, the navigation module 134 refers to stored configuration settings that specify whether the navigation module 134 is to automatically respond to specific types of navigation with the grid overlay. For example, the navigation module 134 can refer to the configuration settings and determine to automatically respond to navigation commands to move a design object 140 by displaying the grid overlay. When the design application 130 determines to perform navigation using the labeled grid 724, the design application proceeds to step 1010. Otherwise, the design application 130 determines not to perform navigation using the labeled grid 724 and proceeds to step 1008.

At step 1010, the design application 130 generates a grid overlay. In various embodiments, the design application 130 can automatically respond to the initial navigation command 620 by updating a view of the design workspace to a graphical overlay that comprises a labeled grid 724 of the design workspace. Each grid area in the labeled grid 724 is labeled with a distinct identifier (e.g., the letter “B” identifying the grid area that contains the selected object point 702(1)) that the user 160 can identify to manipulate design objects 140 and/or update a view of the design workspace.

At step 1012, the design application 130 receives a grid selection command. In various embodiments, upon displaying the graphical overlay of the labeled grid 724, the user 160 can speak a phrase selecting a specific identifier for a grid area within the labeled grid 724. In such instances, the voice recognition module 132 receives the subsequent speech input signal 204 and generates the subsequent navigation command 630. The voice recognition module 132 then transmits the subsequent navigation command 630 to the navigation module 134.

At step 1014, the design application 130 identifies a target location based on the grid selection command. In various embodiments, the navigation module 134 processes the subsequent navigation command 630 to identify the specific identifier. At step 1016, the design application 130 navigates to the identified target location. In various embodiments, the navigation module 134 moves the design object 140 identified in the navigation command to the corresponding grid area. Additionally, or alternatively, the navigation module 134 can also change the view by zooming into an area that includes at least the selected grid area. For example, the navigation module 134 can move the design object 140 to a specific grid area (e.g., the grid area labeled “S”). The navigation module 134 can also zoom in to display a portion of the design workspace including the entirety of the “S” grid area and portions of neighboring grid areas. In some embodiments, the navigation module 134 animates the movement of the selected design 140, then animates the zooming of the camera view. Alternatively, the navigation module 134 can update the design workspace without animating the execution of the navigation command. In this manner, the design application 130 can respond to voice commands of the user 160 by moving the design object 140 to a precise location within the design workspace.

At step 1008, the design application 130 determines whether to perform navigation using a plurality of landmark markers 660. In various embodiments, the navigation module 134 determines whether to respond to the initial navigation command 620 by generating a graphical overlay that includes the plurality of landmark markers 660. In some embodiments, the navigation module 134 refers to stored configuration settings that specify whether the navigation module 134 is to automatically respond to specific types of navigation with the plurality of landmark markers 660. For example, the navigation module 134 can refer to the configuration settings and determine to automatically respond to navigation commands to rotate a design object 140 and/or extend a selected object point 602 by displaying the plurality of landmark markers 660 proximate to candidate landmark locations 640. When the design application 130 determines to perform navigation using the plurality of landmark markers 660, the design application proceeds to step 1020. Otherwise, the design application 130 determines not to perform navigation using the plurality of landmark markers 660 and terminates the method 1000.

At step 1020, the design application 130 identifies candidate landmark locations 640 within the design workspace. In various embodiments, the navigation module 134 determines one or more landmark locations within the design space as candidates for the target location to complete the execution of the navigation specified in the initial navigation command 620. For example, the navigation module 134 can analyze the design space and determine various landmark locations associated with vertices, edges, midpoints, and/or centers of existing design objects (e.g., the existing design objects 610 and 612) included in the design workspace. In such instances, the navigation module 134 can identify and/or display the set of candidate landmark locations 640.

At step 1022, the design application 130 displays landmark markers 660 proximate to the candidate landmark locations 640. In various embodiments, the navigation module 134 generates a graphical overlay comprising a plurality of landmark markers 660 to uniquely identify each of the candidate landmark locations 640 to aid in the execution of the navigation command (e.g., extension of the design object 640 by moving the selected object point 402). The landmark markers 660 can be a set of stored icons, letters, numbers, and/or symbols that can identify a specific candidate landmark location 660. In various embodiments, the navigation module 134 stores phonetically distinct icons to increase the distinguishing features of the icon. For example, the plurality of icons can include a pear, a carrot, and corn, but can exclude a horn. In another example, the markers can be symbols representing code words in a phonetic alphabet (e.g., foxtrot, golf, hotel, India, etc.).

At step 1024, the design application 130 receives a selection of a landmark marker 660. In various embodiments, upon displaying the graphical overlay of landmark markers 660, the user 160 can speak a phrase selecting a specific landmark marker 660. In such instances, the voice recognition module 132 receives the subsequent speech input signal 204 and generates the subsequent navigation command 630. The voice recognition module 132 then transmits the subsequent navigation command 630 to the navigation module 134.

At step 1026, the design application 130 navigates to the corresponding landmark location. In various embodiments, the navigation module 134 executes the navigation command 250 based on the selection specified in the subsequent navigation command 630. For example, the navigation module 134 can move the selected object point 602 to a specific candidate landmark location (e.g., 640(2)) that corresponds to the selected landmark marker 660 (e.g., 660(2)). In this manner, the design application 130 can respond to voice commands of the user 160 by moving the selected object point 602 to a precise location within the design workspace. In various embodiments, the navigation module 134 can animate the movement of the selected object point 602 along the movement path 608, thereby extending the length of the line segment 604 (e.g., 604(2)). Alternatively, the navigation module 134 can snap (e.g., the movement 608) the selected object point 602 to the candidate landmark location 604(3) without animating the movement.

### Example System Architecture

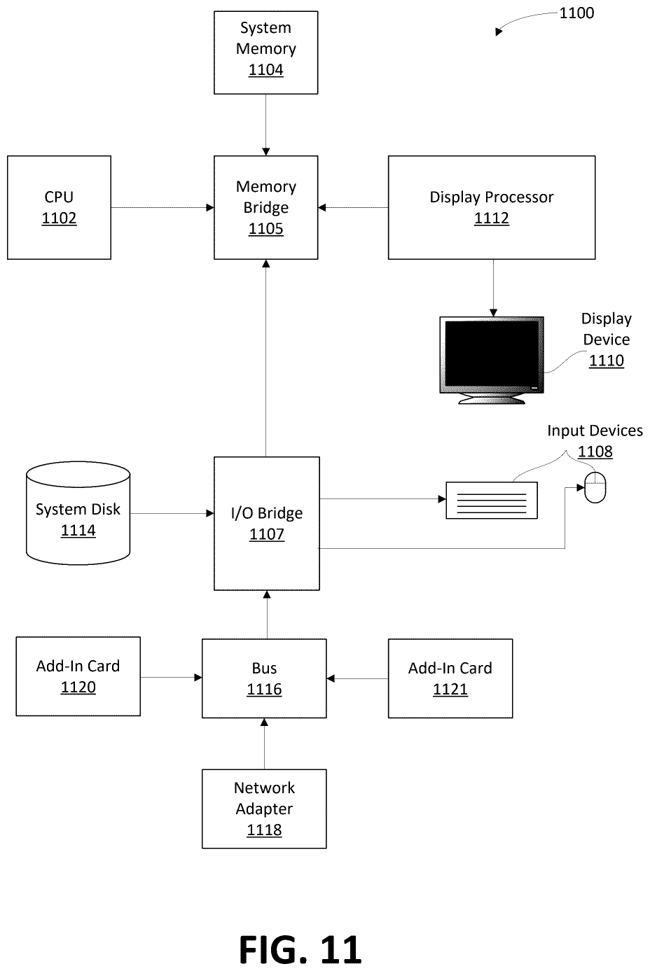

FIG. 11 depicts one architecture of a system 1100 within which the various embodiments may be implemented. This figure in no way limits or is intended to limit the scope of the present disclosure. In various implementations, system 1100 may be an augmented reality, virtual reality, or mixed reality system or device, a personal computer, video game console, personal digital assistant, mobile phone, mobile device, or any other device suitable for practicing one or more embodiments of the present disclosure. Further, in various embodiments, any combination of two or more systems 1100 may be coupled together to practice one or more aspects of the present disclosure.

As shown, system 1100 includes a central processing unit (CPU) 1102 and a system memory 1104 communicating via a bus path that may include a memory bridge 1105. CPU 1102 includes one or more processing cores, and, in operation, CPU 1102 is the master processor of system 1100, controlling and coordinating operations of other system components. System memory 1104 stores software applications and data for use by CPU 1102. CPU 1102 runs software applications and optionally an operating system. Memory bridge 1105, which may be, e.g., a Northbridge chip, is connected via a bus or other communication path (e.g., a HyperTransport link) to an I/O (input/output) bridge 1107. I/O bridge 1107, which may be, e.g., a Southbridge chip, receives user input from one or more user input devices 1108 (e.g., keyboard, mouse, joystick, digitizer tablets, touch pads, touch screens, still or video cameras, motion sensors, and/or microphones) and forwards the input to CPU 1102 via memory bridge 1105.

A display processor 1112 is coupled to memory bridge 1105 via a bus or other communication path (e.g., a PCI Express, Accelerated Graphics Port, or HyperTransport link); in one embodiment display processor 1112 is a graphics subsystem that includes at least one graphics processing unit (GPU) and graphics memory. Graphics memory includes a display memory (e.g., a frame buffer) used for storing pixel data for each pixel of an output image. Graphics memory can be integrated in the same device as the GPU, connected as a separate device with the GPU, and/or implemented within system memory 1104.

Display processor 1112 periodically delivers pixels to a display device 1112 (e.g., a screen or conventional CRT, plasma, OLED, SED or LCD based monitor or television). Additionally, display processor 1112 may output pixels to film recorders adapted to reproduce computer generated images on photographic film. Display processor 1112 can provide display device 1110 with an analog or digital signal. In various embodiments, one or more of the various graphical user interfaces set forth in Appendices A-J, attached hereto, are displayed to one or more users via display device 1110, and the one or more users can input data into and receive visual output from those various graphical user interfaces.

A system disk 1114 is also connected to I/O bridge 1107 and may be configured to store content and applications and data for use by CPU 1102 and display processor 1112. System disk 1114 provides non-volatile storage for applications and data and may include fixed or removable hard disk drives, flash memory devices, and CD-ROM, DVD-ROM, Blu-ray, HD-DVD, or other magnetic, optical, or solid state storage devices.

A switch 1116 provides connections between I/O bridge 1107 and other components such as a network adapter 1118 and various add-in cards 1120 and 1121. Network adapter 1118 allows system 1100 to communicate with other systems via an electronic communications network, and may include wired or wireless communication over local area networks and wide area networks such as the Internet.

Other components (not shown), including USB or other port connections, film recording devices, and the like, may also be connected to I/O bridge 1107. For example, an audio processor may be used to generate analog or digital audio output from instructions and/or data provided by CPU 1102, system memory 1104, or system disk 1114. Communication paths interconnecting the various components in FIG. 1 may be implemented using any suitable protocols, such as PCI (Peripheral Component Interconnect), PCI Express (PCI-E), AGP (Accelerated Graphics Port), HyperTransport, or any other bus or point-to-point communication protocol(s), and connections between different devices may use different protocols, as is known in the art.

In one embodiment, display processor 1112 incorporates circuitry optimized for graphics and video processing, including, for example, video output circuitry, and constitutes a graphics processing unit (GPU). In another embodiment, display processor 1112 incorporates circuitry optimized for general purpose processing. In yet another embodiment, display processor 1112 may be integrated with one or more other system elements, such as the memory bridge 1105, CPU 1102, and I/O bridge 1107 to form a system on chip (SoC). In still further embodiments, display processor 1112 is omitted and software executed by CPU 1102 performs the functions of display processor 1112.

Pixel data can be provided to display processor 1112 directly from CPU 1102. In some embodiments of the present disclosure, instructions and/or data representing a scene are provided to a render farm or a set of server computers, each similar to system 1100, via network adapter 1118 or system disk 1114. The render farm generates one or more rendered images of the scene using the provided instructions and/or data. These rendered images may be stored on computer-readable media in a digital format and optionally returned to system 1100 for display. Similarly, stereo image pairs processed by display processor 1112 may be output to other systems for display, stored in system disk 1114, or stored on computer-readable media in a digital format.

Alternatively, CPU 1102 provides display processor 1112 with data and/or instructions defining the desired output images, from which display processor 1112 generates the pixel data of one or more output images, including characterizing and/or adjusting the offset between stereo image pairs. The data and/or instructions defining the desired output images can be stored in system memory 1104 or graphics memory within display processor 1112. In an embodiment, display processor 1112 includes 3D rendering capabilities for generating pixel data for output images from instructions and data defining the geometry, lighting shading, texturing, motion, and/or camera parameters for a scene. Display processor 1112 can further include one or more programmable execution units capable of executing shader programs, tone mapping programs, and the like.

Further, in other embodiments, CPU 1102 or display processor 1112 may be replaced with or supplemented by any technically feasible form of processing device configured process data and execute program code. Such a processing device could be, for example, a central processing unit (CPU), a graphics processing unit (GPU), an application-specific integrated circuit (ASIC), a field-programmable gate array (FPGA), and so forth. In various embodiments any of the operations and/or functions described herein can be performed by CPU 1102, display processor 1112, or one or more other processing devices or any combination of these different processors.

CPU 1102, render farm, and/or display processor 1112 can employ any surface or volume rendering technique known in the art to create one or more rendered images from the provided data and instructions, including rasterization, scanline rendering REYES or micropolygon rendering, ray casting, ray tracing, image-based rendering techniques, and/or combinations of these and any other rendering or image processing techniques known in the art.

In other contemplated embodiments, system 1100 may be a robot or robotic device and may include CPU 1102 and/or other processing units or devices and system memory 1104. In such embodiments, system 1100 may or may not include other elements shown in FIG. 1. System memory 1104 and/or other memory units or devices in system 1100 may include instructions that, when executed, cause the robot or robotic device represented by system 1100 to perform one or more operations, steps, tasks, or the like.

It will be appreciated that the system shown herein is illustrative and that variations and modifications are possible. The connection topology, including the number and arrangement of bridges, may be modified as desired. For instance, in some embodiments, system memory 1104 is connected to CPU 1102 directly rather than through a bridge, and other devices communicate with system memory 1104 via memory bridge 1105 and CPU 1102. In other alternative topologies display processor 1112 is connected to I/O bridge 1107 or directly to CPU 1102, rather than to memory bridge 1105. In still other embodiments, I/O bridge 1107 and memory bridge 1105 might be integrated into a single chip. The particular components shown herein are optional; for instance, any number of add-in cards or peripheral devices might be supported. In some embodiments, switch 1116 is eliminated, and network adapter 1118 and add-in cards 1120, 1121 connect directly to I/O bridge 1107.

In sum, a design application includes a voice recognition module that interprets voice commands provided by a user, and a navigation module that executes the voice commands for manipulating objects or modifying a view of a design workspace. The voice recognition module receives a voice command as one or more speech input signals. The voice recognition module processes the speech signals and generates one or more commands and transmits the commands to the navigation module. The navigation module responds based on the type of command. The navigation module can manipulate one or more objects within the design workspace in response to lengthened commands and navigation commands. The navigation module can also modify the view of the design workspace based on navigation commands.

When the voice recognition module identifies a lengthened command, a user speaks a word or phrase using expressive lengthening for controlling the execution of a command, with the pronunciation of a syllable extended to control the execution of a command. The lengthened command includes an initial command portion that the navigation module first recognizes to identify the speech input as a lengthened command and the target within the design workspace that is subject to the command. The lengthened command also includes one or more lengthened command portions that the navigation module recognizes as instructions to continually execute while the user continues with the pronunciation of the syllable. As the user continues with the pronunciation of the lengthened command portion, the navigation module continues execution of the corresponding lengthened command in real-time. Once the user finishes pronouncing the syllable, the voice recognition module ends the generation of lengthened command portions and the navigation module determines that the lengthened command is complete.

When the voice recognition module identifies a navigation command, a user speaks a phrase to manipulate the location of a design object or a point within the design workspace. The navigation module receives the navigation command and automatically generates navigation tools within the workspace to aid the user in selecting a precise location or area within the design workspace. The navigation module can automatically respond to the navigation command by identifying a group of candidate landmark locations within the design workspace. The navigation module can then add distinct markers at each of the candidate landmark locations. When the user voices a term for one of the distinct markers, the navigation module completes the navigation by moving the design object or point to the landmark location corresponding to the distinct marker. The navigation module can additionally or alternatively respond to the navigation command by automatically generating a labeled grid overlay of the design workspace where each grid area is labeled with a distinct identifier. When the user voices a term for a distinct identifier, the navigation module moves the design object or point to the grid area corresponding to the distinct identifier. The navigation module can also update the view of the design workspace by zooming in to the specific grid area. The navigation module can recursively add grid overlays and zoom into selected grid areas to display an exact point within the design workspace and cause the design object or point to move to the exact point.

At least one technical advantage of the disclosed techniques relative to the prior art is that with the disclosed techniques, a computing device can respond to speech inputs with precise navigation and manipulation within a design workspace. In particular, a computing device implementing the disclosed design application can recognize and respond to specific types of voice commands and execute precise navigational controls in response to the voice command. In this manner, the disclosed design application can respond to a wider range of user inputs with precision when compared to conventional design applications that did not respond to such types of voice commands. A user interacting with the computing device implementing the disclosed design application can utilize voice commands to precisely manipulate objects or navigate within a design workspace without the need for manual input devices, such as a digital pen or mouse, which enhances the accessibility of the design application to a wider range of users and in a wider range of environments.
1. In various embodiments, a computer-implemented method for navigating design workspaces comprises acquiring, via an audio sensor, a speech input signal of a user, detecting, in the speech input signal, an initial lengthened command portion for a lengthened command to move at least a portion of a design object within a design workspace, detecting a lengthened command portion in a subsequent input signal of the user, in response to detecting the lengthened command portion, executing the lengthened command, where executing the lengthened command continues as the user continues to provide the subsequent input signal, and terminating execution of the lengthened command upon detecting an end of the lengthened command portion.
2. The computer-implemented method of clause 1, where the initial lengthened command portion includes an identification of the design object.
3. The computer-implemented method of clause 1 or 2, further comprising determining a movement path for at least the portion of the design object based on the initial lengthened command portion, where the initial lengthened command portion includes a movement direction.
4. The computer-implemented method of any of clauses 1-3, where the lengthened command portion includes a manipulation phrase that includes a lengthened syllable. and the user continues to provide the subsequent input signal by pronouncing the lengthened syllable.
5. The computer-implemented method of any of clauses 1-4, where the lengthened command portion includes a manipulation phrase and an extendible sound, and the user continues to provide the subsequent input signal by uttering the extendible sound.
6. The computer-implemented method of any of clauses 1-5, where the portion of the design object comprises a point on the design object, and moving the point changes one or more dimensions of the design object.
7. The computer-implemented method of any of clauses 1-6, where at least the portion of the design object comprises an entirety of the design object.
8. The computer-implemented method of any of clauses 1-5, further comprising identifying a set of candidate target locations within the design workspace.
9. The computer-implemented method of any of clauses 1-8, where the portion of the design object snaps to a first candidate location included in the set of candidate target locations.
10.The computer-implemented method of any of clauses 1-9, where the portion of the design object remains at a first candidate location included in the set of candidate target locations while the lengthened command continues.
11. In various embodiments, one or more non-transitory computer-readable media store instructions that, when executed by one or more processors, cause the one or more processors to navigate design workspaces, by performing the steps of acquiring, via an audio sensor, a speech input signal of a user, detecting, in the speech input signal, an initial lengthened command portion for a lengthened command to move at least a portion of a design object within a design workspace, detecting a lengthened command portion in a subsequent input signal of the user, in response to detecting the lengthened command portion, executing the lengthened command, where executing the lengthened command continues as the user continues to provide the subsequent input signal, and terminating execution of the lengthened command upon detecting an end of the lengthened command portion.
12. The one or more non-transitory computer-readable media of clause 11, where a speed of movement for the portion of the design object is based on one or more tonal characteristics of the subsequent input signal.
13. The one or more non-transitory computer-readable media of clause 11 or 12, where at least one of a speed of movement or a direction of movement is based on visual sensor data associated of the user when providing the subsequent input signal.
14. The one or more non-transitory computer-readable media of any of clauses 11-13, where detecting an end of the lengthened command portion comprises receiving an input from an input device, where the input device is distinct from the audio sensor.
15. The one or more non-transitory computer-readable media of any of clauses 11-14, where the lengthened command portion includes a manipulation phrase that includes a lengthened syllable, and the user continues to provide the subsequent input signal by pronouncing the lengthened syllable.
16. The one or more non-transitory computer-readable media of any of clauses 11-15, further comprising instructions that, when executed by the one or more processors, cause the one or more processors to perform the step of identifying a set of candidate target locations within the design workspace, where the portion of the design object snaps to a first candidate location included in the set of candidate target locations, or the portion of the design object remains at the first candidate location included in the set of candidate target locations while the lengthened command continues.
17. The one or more non-transitory computer-readable media of any of clauses 11-16, further comprising instructions that, when executed by the one or more processors, cause the one or more processors to perform the step of determining a movement path for the portion of the design object based on the initial lengthened command portion, where the initial lengthened command portion includes an identification of the design object and a movement direction.
18. The one or more non-transitory computer-readable media of any of clauses 11-17, where the portion of the design object comprises a point on the design object, and moving the point changes one or more dimensions of the design object.
19. The one or more non-transitory computer-readable media of any of clauses 11-18, where the portion of the design object comprises an entirety of the design object.
20. In various embodiments, a system comprises one or more memories storing instructions. and one or more processors coupled to the one or more memories that, when executing the instructions, cause the one or more processors to navigate design workspaces, by performing the steps of acquiring, via an audio sensor, a speech input signal of a user, detecting, in the speech input signal, an initial lengthened command portion for a lengthened command to move at least a portion of a design object within a design workspace, detecting a lengthened command portion in a subsequent input signal of the user, in response to detecting the lengthened command portion, executing the lengthened command, where executing the lengthened command continues as the user continues to provide the subsequent input signal, and terminating execution of the lengthened command upon detecting an end of the lengthened command portion.
21. In various embodiments, a computer-implemented method for navigating design workspaces comprises acquiring, via an audio sensor, a speech input signal of a user, detecting, in the speech input signal, a navigation command portion to move at least a portion of a design object within a design workspace, in response to detecting the navigation command portion, automatically generating a graphical overlay over at least a portion of the design workspace, where the graphical overlay includes a plurality of identifiers, detecting a subsequent navigation command identifying a selection of a first identifier included in the plurality of identifiers, and moving the portion of the design object to a location associated with the first identifier.
22. The computer-implemented method of clause 21, where the graphical overlay comprises a plurality of landmark markers, and each identifier included in the plurality of identifiers corresponds to a landmark marker included in the plurality of landmark markers.
23. The computer-implemented method of clause 21 or 22, further comprising determining a plurality of candidate landmark locations within the design workspace.
24. The computer-implemented method of any of clauses 21-23, where the plurality of candidate landmark locations are based on an alignment with one or more points of the design object, or an alignment with one or more points of one or more other existing objects within the design workspace.
25. The computer-implemented method of any of clauses 21-24, where each landmark marker included in the plurality of landmark markers comprise an icon proximate to a candidate location included in the plurality of candidate landmark locations.
26. The computer-implemented method of any of clauses 21-25, where a first copy of an icon is displayed proximate to a first candidate landmark location corresponding to a first point on a first neighboring object, and a second copy of the icon is displayed proximate to a second candidate landmark location corresponding to a second point on a second neighboring object, where the first neighboring object and the second neighboring object share a common shape.
27.The computer-implemented method of any of clauses 21-26, where the graphical overlay comprises a labeled grid, where each identifier included in the plurality of identifiers corresponds to a distinct grid area defined by the labeled grid.
28. The computer-implemented method of any of clauses 21-27, further comprising upon moving the portion of the design object to the location associated with the first identifier, updating a view of the design workspace to display a zoomed-in view of a grid area corresponding to the first identifier.
29. The computer-implemented method of any of clauses 21-28, further comprising generating a second graphical overlay over the zoomed-in view of the grid area corresponding to the first identifier, where the second graphical overlay comprises one of a second labeled grid, where each second identifier included in a plurality of second identifiers corresponds to a distinct second grid area, or a plurality of landmark markers, where each second identifier included in the plurality of second identifiers corresponds to a landmark marker included in the plurality of landmark markers.
30. The computer-implemented method of any of clauses 21-29, where the labeled grid defines a plurality of non-uniform distinct grid areas.
31. The computer-implemented method of any of clauses 21-30, where a size of a non-uniform distinct grid area included in the plurality of non-uniform distinct grid areas is inversely proportional to a quantity of design objects included in the non-uniform distinct grid area.
32. In various embodiments, one or more non-transitory computer-readable media store instructions that, when executed by one or more processors, cause the one or more processors to navigate design workspaces, by performing the steps of acquiring, via an audio sensor, a speech input signal of a user, detecting, in the speech input signal, a navigation command portion to move at least a portion of a design object within a design workspace, in response to detecting the navigation command portion, automatically generating a graphical overlay over at least a portion of the design workspace, where the graphical overlay includes a plurality of identifiers, detecting a subsequent navigation command identifying a selection of a first identifier included in the plurality of identifiers, and moving the portion of the design object to a location associated with the first identifier.
33. The one or more non-transitory computer-readable media of clause 32, where the portion of the design object comprises a point on the design object, and moving the point changes one or more dimensions of the design object.
34. The one or more non-transitory computer-readable media of clause 32 and 33, where at least the portion of the design object comprises an entirety of the design object.
35. The one or more non-transitory computer-readable media of any of clauses 32-34, further comprising instructions that, when executed by the one or more processors, cause the one or more processors to perform the step of determining a plurality of candidate landmark locations within the design workspace, where the graphical overlay comprises a plurality of landmark markers, and each identifier included in the plurality of identifiers corresponds to a landmark marker included in the plurality of landmark markers.
36. The one or more non-transitory computer-readable media of any of clauses 32-35, where the plurality of candidate landmark locations are based on an alignment with one or more points of the design object, or an alignment with one or more points of one or more other existing design objects within the design workspace.
37. The one or more non-transitory computer-readable media of any of clauses 32-36, where the graphical overlay comprises a labeled grid, where each identifier included in the plurality of identifiers corresponds to a distinct grid area defined by the labeled grid.
38. The one or more non-transitory computer-readable media of any of clauses 32-37, further comprising instructions that, when executed by the one or more processors, cause the one or more processors to perform the step of upon moving the portion of the design object to the location associated with the first identifier, updating a view of the design workspace to display a zoomed-in view of a grid area corresponding to the first identifier.
39. The one or more non-transitory computer-readable media of any of clauses 32-38, further comprising instructions that, when executed by the one or more processors, cause the one or more processors to perform the step of generating a second graphical overlay over the zoomed-in view of the grid area corresponding to the first identifier, where the second graphical overlay comprises one of a second labeled grid, where each second identifier included in a plurality of second identifiers corresponds to a distinct second grid area, or a plurality of landmark markers, where each second identifier included in the plurality of second identifiers corresponds to a landmark marker included in the plurality of landmark markers.
40. In various embodiments, a system comprises one or more memories storing instructions, and one or more processors coupled to the one or more memories that, when executing the instructions, cause the one or more processors to navigate design workspaces, by performing the steps of acquiring, via an audio sensor, a speech input signal of a user, detecting, in the speech input signal, a navigation command portion to move at least a portion of a design object within a design workspace, in response to detecting the navigation command portion, automatically generating a graphical overlay over at least a portion of the design workspace, where the graphical overlay includes a plurality of identifiers, detecting a subsequent navigation command identifying a selection of a first identifier included in the plurality of identifiers, and moving the portion of the design object to a location associated with the first identifier.

Any and all combinations of any of the claim elements recited in any of the claims and/or any elements described in this application, in any fashion, fall within the contemplated scope of the present invention and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “module,” a “system,” or a “computer.” In addition, any hardware and/or software technique, process, function, component, engine, module, or system described in the present disclosure may be implemented as a circuit or set of circuits. Furthermore, aspects of the present disclosure may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable gate arrays.

The flowchart and block diagrams in the figures illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the preceding is directed to embodiments of the present disclosure, other and further embodiments of the disclosure may be devised without departing from the basic scope thereof, and the scope thereof is determined by the claims that follow.

What is claimed is:

1. A computer-implemented method for navigating design workspaces, the method comprising:
acquiring, via an audio sensor, a speech input signal of a user;
detecting, in the speech input signal, an initial lengthened command portion for a lengthened command to move at least a portion of a design object within a design workspace;
detecting a lengthened command portion in a subsequent input signal of the user;
in response to detecting the lengthened command portion, executing the lengthened command, wherein executing the lengthened command continues as the user continues to provide the subsequent input signal; and
terminating execution of the lengthened command upon detecting an end of the lengthened command portion.

2. The computer-implemented method of claim 1, wherein the initial lengthened command portion includes an identification of the design object.

3. The computer-implemented method of claim 1, further comprising:
determining a movement path for at least the portion of the design object based on the initial lengthened command portion, wherein the initial lengthened command portion includes a movement direction.

4. The computer-implemented method of claim 1, wherein:
the lengthened command portion includes a manipulation phrase that includes a lengthened syllable; and
the user continues to provide the subsequent input signal by pronouncing the lengthened syllable.

5. The computer-implemented method of claim 1, wherein:
the lengthened command portion includes a manipulation phrase and an extendible sound; and
the user continues to provide the subsequent input signal by uttering the extendible sound.

6. The computer-implemented method of claim 1, wherein:
the portion of the design object comprises a point on the design object; and
moving the point changes one or more dimensions of the design object.

7. The computer-implemented method of claim 1, wherein at least the portion of the design object comprises an entirety of the design object.

8. The computer-implemented method of claim 1, further comprising:
identifying a set of candidate target locations within the design workspace.

9. The computer-implemented method of claim 8, wherein the portion of the design object snaps to a first candidate location included in the set of candidate target locations.

10. The computer-implemented method of claim 8, wherein the portion of the design object remains at a first candidate location included in the set of candidate target locations while the lengthened command continues.

11. One or more non-transitory computer-readable media storing instructions that, when executed by one or more processors, cause the one or more processors to navigate design workspaces, by performing the steps of:
acquiring, via an audio sensor, a speech input signal of a user;
detecting, in the speech input signal, an initial lengthened command portion for a lengthened command to move at least a portion of a design object within a design workspace;
detecting a lengthened command portion in a subsequent input signal of the user;
in response to detecting the lengthened command portion, executing the lengthened command, wherein executing the lengthened command continues as the user continues to provide the subsequent input signal; and
terminating execution of the lengthened command upon detecting an end of the lengthened command portion.

12. The one or more non-transitory computer-readable media of claim 11, wherein a speed of movement for the portion of the design object is based on one or more tonal characteristics of the subsequent input signal.

13. The one or more non-transitory computer-readable media of claim 11, wherein at least one of a speed of movement or a direction of movement is based on visual sensor data associated of the user when providing the subsequent input signal.

14. The one or more non-transitory computer-readable media of claim 11, wherein detecting an end of the lengthened command portion comprises receiving an input from an input device, wherein the input device is distinct from the audio sensor.

15. The one or more non-transitory computer-readable media of claim 11, wherein:
the lengthened command portion includes a manipulation phrase that includes a lengthened syllable; and
the user continues to provide the subsequent input signal by pronouncing the lengthened syllable.

16. The one or more non-transitory computer-readable media of claim 11, further comprising instructions that, when executed by the one or more processors, cause the one or more processors to perform the step of identifying a set of candidate target locations within the design workspace, wherein:
the portion of the design object snaps to a first candidate location included in the set of candidate target locations; or
the portion of the design object remains at the first candidate location included in the set of candidate target locations while the lengthened command continues.

17. The one or more non-transitory computer-readable media of claim 11, further comprising instructions that, when executed by the one or more processors, cause the one or more processors to perform the step of:
determining a movement path for the portion of the design object based on the initial lengthened command portion,
wherein the initial lengthened command portion includes an identification of the design object and a movement direction.

18. The one or more non-transitory computer-readable media of claim 11, wherein:
the portion of the design object comprises a point on the design object; and
moving the point changes one or more dimensions of the design object.

19. The one or more non-transitory computer-readable media of claim 11, wherein the portion of the design object comprises an entirety of the design object.

20. A system comprising:
one or more memories storing instructions; and
one or more processors coupled to the one or more memories that, when executing the instructions, cause the one or more processors to navigate design workspaces, by performing the steps of:
acquiring, via an audio sensor, a speech input signal of a user;
detecting, in the speech input signal, an initial lengthened command portion for a lengthened command to move at least a portion of a design object within a design workspace;
detecting a lengthened command portion in a subsequent input signal of the user;
in response to detecting the lengthened command portion, executing the lengthened command, wherein executing the lengthened command continues as the user continues to provide the subsequent input signal; and
terminating execution of the lengthened command upon detecting an end of the lengthened command portion.
